(19) United States
(12) Patent Application Publication
(10) Pub. No.: US 2024/0339984 A1
(43) Pub. Date: Oct. 10, 2024

(54) BALUN CIRCUIT AND SEMICONDUCTOR DEVICE

(71) Applicant: Renesas Electronics Corporation, Tokyo (JP)

(72) Inventors: Kenichi SHIBATA, Tokyo (JP); Yuichi KUSAKA, Tokyo (JP)

(73) Assignee: Renesas Electronics Corporation, Tokyo (JP)

(21) Appl. No.: 18/588,149

(22) Filed: Feb. 27, 2024

(30) Foreign Application Priority Data
Apr. 10, 2023 (JP) 2023-063176

(51) Int. Cl. H03H 7/42; H03F 3/213; H03H 7/38

(52) U.S. Cl. CPC H03H 7/422; H03F 3/213; H03H 7/38; H03F 2200/09; H03F 2200/451

(57) ABSTRACT

A balun circuit is disclosed. The balun circuit is provided between a transmitter and a common antenna terminal to which the transmitter and a receiver are coupled. The balun includes an inductor L1 coupled at one or both ends to the transmitter, an input node of the receiver, and an inductor L2 provided between ground or a first biasing power supply. The inductor L2 includes an inductor having a mutual inductance with the inductor L1. The inductor L2 is a variable inductor.

### CROSS-REFERENCE TO RELATED APPLICATION

This application claims priority under 35 U.S.C. § 119 to Japanese Patent Application No. 2023-063176 filed on Apr. 10, 2023. The disclosure of Japanese Patent Application No. 2023-063176, including the specification, drawings and abstract, is incorporated herein by reference in its entirety.

### BACKGROUND

The present disclosure relates to a balun circuit and a semiconductor device.

There are disclosed techniques listed below.
[Patent Document 1] Japanese Unexamined Patent Application Publication No. 2018/88707

Patent Document 1 discloses a technique related to a RFIC (Radio Frequency Integrated Circuit) in which a low noise amplifier for reception and a power amplifier for transmission are coupled to a common antenna terminal. By changing the capacitance values of the two capacitive elements included in the impedance matching circuit dedicated to transmit, the loss of the high-frequency signal is reduced.

### SUMMARY

When the conventional RFIC does not include an impedance matching circuit dedicated to transmit, it is difficult to prevent deterioration in reception performance while suppressing loss at the time of transmission.

Other objects and novel features will become apparent from the description of this specification and the accompanying drawings.

A balun circuit according to an embodiment comprises a balun circuit provided between a transmitter and a common antenna terminal to which the transmitter and a receiver are coupled. The balun circuit comprises a first inductor coupled at one or both ends to the transmitter, and a second inductor provided between an input node of the receiver, and a ground or a first bias power supply, wherein the second inductor comprises an inductor having a mutual inductance with the first inductor, and the second inductor is a variable inductor.

A semiconductor device according to an embodiment comprises a transmitter, a receiver, and a balun circuit provided between the transmitter and a common antenna terminal to which the transmitter and the receiver are coupled, and wherein the balun circuit further comprises a first inductor coupled at one or both ends to the transmitter, and a second inductor provided between an input node of the receiver, and ground or a first bias power supply, and wherein the second inductor includes an inductor having a mutual inductance with the first inductor, and the second inductor is a variable inductor.

According to the embodiment, the inductance value of the inductor included in the balun circuit can be changed between the transmission operation and the reception operation.

### BRIEF DESCRIPTION OF THE DRAWINGS

FIG. 1 is a diagram for explaining a configuration of a semiconductor device according to a first embodiment.

FIG. 2 is a diagram for explaining a configuration of a semiconductor device according to modified example of the first embodiment.

FIG. 3 is a diagram for explaining a configuration of a semiconductor device according to a second embodiment.

FIG. 4 is a diagram for explaining a configuration of a semiconductor device according to modified example of the second embodiment.

FIG. 5 is a diagram for explaining a configuration of a semiconductor device according to a third embodiment.

FIG. 6 is a diagram for explaining a configuration of a semiconductor device according to modified example of the third embodiment.

FIG. 7 is a diagram for explaining a configuration of a semiconductor device according to a fourth embodiment.

FIG. 8 is a diagram for explaining a configuration of a semiconductor device according to a first modified example of the fourth embodiment.

FIG. 9 is a diagram for explaining a configuration of a semiconductor device according to a second modified example of the fourth embodiment.

FIG. 10 is a diagram for explaining a configuration of a semiconductor device according to a third modified example of the fourth embodiment.

### DETAILED DESCRIPTION

For clarity of explanation, the following description and drawings are appropriately omitted and simplified. In addition, the elements described in the drawings as functional blocks for performing various processes can be configured as CPUs (Central Processing Unit), memories, and other circuits in terms of hardware, and are realized by programs loaded into the memories in terms of software. Therefore, it is understood by those skilled in the art that these functional blocks can be realized in various forms by hardware alone, software alone, or a combination thereof, and the present disclosure is not limited to any of them. In the drawings, the same elements are denoted by the same reference numerals, and a repetitive description thereof is omitted as necessary.

The above-described program also includes instructions (or software code) for causing a computer to perform one or more of the functions described in the embodiments when the program is loaded into the computer. The program may be stored in a non-transitory computer-readable medium or a tangible storage medium. By way of example, and not limitation, computer-readable media or tangible storage media include random-access memory (RAM), read-only memory (ROM), flash memory, solid-state drive (SSD) or other memory techniques, CD-ROM, digital versatile disc (DVD), Blu-ray disk or other optical disk storage, magnetic cassettes, magnetic tape, magnetic disk storage or other magnetic storage devices. The program may be transmitted on a transitory computer readable medium or a communication medium. By way of example, and not limitation, transitory computer-readable media or communication media include electrical, optical, acoustic, or other forms of propagated signals.

### First Embodiment

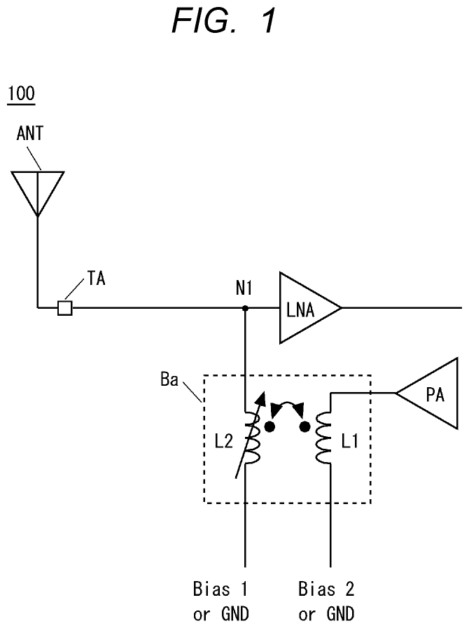

FIG. 1 is a diagram illustrating a configuration of a semiconductor device 100 according to a first embodiment. The semiconductor device 100 includes an antenna terminal TA, a low noise amplifier LNA, a power amplifier PA, and a balun circuit Ba. The low noise amplifier LNA, the power amplifier PA, and the balun circuit Ba may be formed on a single semiconductor chip.

The antenna terminal TA is coupled to an antenna ANT. The antenna terminal TA is a common antenna terminal to which a transmitter and a receiver are coupled. The semiconductor device 100 may have one input/output pin for RF.

The low noise amplifier LNA is provided at a first stage of the receiver. The power amplifier PA is provided at a last stage of the transmitter.

For example, the low noise amplifier LNA may be configured to be supplied with power via a first power switch (not shown), and the power amplifier PA may be configured to be supplied with power via a second power switch (not shown). The first and second power switches switch between supplying and shutting off a power to the low-noise amplifier LNA and the power amplifier PA respectively in accordance with an instruction from an amplifier control circuit (not shown). The amplifier control circuit operates the low noise amplifier LNA and the power amplifier PA exclusively. That is, during a reception operation, the low noise amplifier LNA operates, and the power amplifier PA does not operate. During a transmission operation, the power amplifier PA operates and the low noise amplifier LNA does not operate. Since the low-noise amplifier LNA does not operate during the transmission operation, the low-noise amplifier LNA has a large impedance and a small loss during transmission.

An impedance matching circuit (not shown) may be provided in a path between an input node N1 of the low-noise amplifier LNA and the antenna terminal TA. The impedance matching circuit is a circuit in which an impedance matching circuit for reception and an impedance matching circuit for transmission are shared. Note that the impedance matching circuit can also not be included in the first embodiment.

The balun circuit Ba is provided between the antenna terminal TA and the power amplifier PA. The balun circuit Ba includes an inductor L1 and an inductor L2. The balun circuit Ba is, for example, a circuit that converts an unbalanced signal outputted from the power amplifier PA into a balanced signal.

A first terminal of the inductor L1 is coupled to an output terminal of the power amplifier PA. A second terminal of the inductor L1 is coupled to a ground or a bias voltage source (also referred to as a second bias power supply).

The inductor L2 is provided between the input node N1 of the low noise amplifier LNA, and the ground or the bias power supply (also referred to as a first bias power supply). For example, the first terminal of the inductor L2 is coupled to the input node N1 and the second terminal of the inductor L2 is coupled to the ground or the first bias power supply. The first bias power supply and the second bias power supply may be the same power supply or may be separate power supplies.

The inductor L2 may include a plurality of inductors (also referred to as inductor elements). In this case, a plurality of inductors may be coupled in series with each other. The illustrated inductor L2 may be considered as schematically representing inductance components included in a path between the input node N1 and the ground, etc.

The inductor L2 includes an inductor having a mutual inductance with the inductor L1. The inductor having a mutual inductance with the inductor L1 is also referred to as a secondary inductor. For example, the inductor L2 may include the secondary inductor and a choke coil coupled in series to the secondary inductor. Of course, the inductor L2 may be composed of a single inductance device. The inductor L2 may be, for example, a choke coil having a mutual inductance with the inductor L1.

The inductor L2 is a variable inductor. If the inductor L2 comprises a plurality of inductors, not all inductors need be configured as variable inductors. Further, the secondary inductor does not need to be configured as a variable inductor. An inductor (e.g., choke coil) coupled in series with the secondary inductor may be configured as a variable inductor.

The inductance of the inductor L2 is changed in response to a signal from a control circuit (not shown). For example, the inductor L2 may comprise switches and inductor elements coupled in parallel, and the switch may be switched between an on state and an off state. The inductor L2 is not limited to the above-described configuration, and may comprise any known circuitry.

Alternatively, a variable impedance, such as a switch, may be coupled in parallel to the inductor L1. For example, by switching between the on state and the off state of the switch, the equivalent inductance value of the secondary inductor can be switched.

The inductance of the inductor L2 may be controlled to be large during the reception operation and small during the transmission operation. That is, the inductance value during the reception operation may be larger than the inductance value during the transmission operation. Accordingly, it is possible to prevent degradation in reception performance while suppressing loss at the time of transmission.

When the inductor L2 includes the secondary inductor and the choke coil, the switch (not shown) is coupled in parallel to the choke coil. During the reception operation, the switch is controlled to the off state, and during the transmission operation, the switch is controlled to the on state. Therefore, the inductance value is large during the reception operation, and the inductance value is small during the transmission operation. The switch may be coupled in parallel to the secondary inductor.

In addition, during the reception operation, the switch coupled in parallel to the inductor L1 may be controlled to be in the on state, and during the transmission operation, the switch coupled in parallel to the inductor L1 may be controlled to be in the off state. During the reception operation, the equivalent inductance value of the secondary inductor decreases. Thus, it is possible to prevent the reception performance from deteriorating due to mutual inductance.

Note that both the choke coil and the secondary inductor may be variable inductors. In this case, the sum of the two inductance values may be designed to be large during the reception operation and small during the transmission operation.

In the semiconductor device according to the first embodiment, the inductance of the inductor included in the balun circuit Ba can be changed between the transmission operation and the reception operation.

The semiconductor device according to the first embodiment can share both a transmission terminal and a reception terminal. Further, since it is not necessary to provide an antenna switch for switching the connection destination of the antenna to the circuit for transmission and the circuit for reception, there is an advantage that the loss during the reception operation is small and the delay amount is small.

The semiconductor device according to the first embodiment may be applied to UWB (Ultra Wide Band) or BLE (Bluetooth Low Energy). In particular, the semiconductor device 100 may transmit and receive signals having 500 MHz or higher frequencies.

### Modified Example

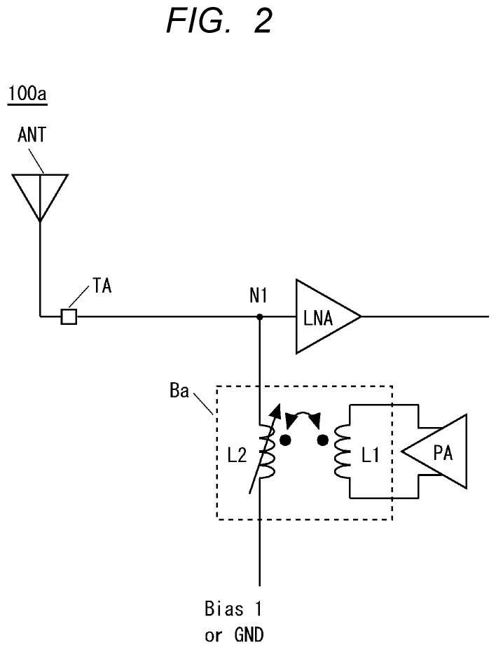

FIG. 2 is a diagram for explaining a configuration of a semiconductor device 100a according to a modified example of the first embodiment. Comparing FIG. 1 and FIG. 2, the power amplifier PA changes from a single-ended type to a differential type. A differential output terminal of the power amplifier PA is coupled to both ends of the inductor L1. The semiconductor device 100a in which the power amplifier PA is of a differential type has the same advantages as the semiconductor device 100.

### Second Embodiment

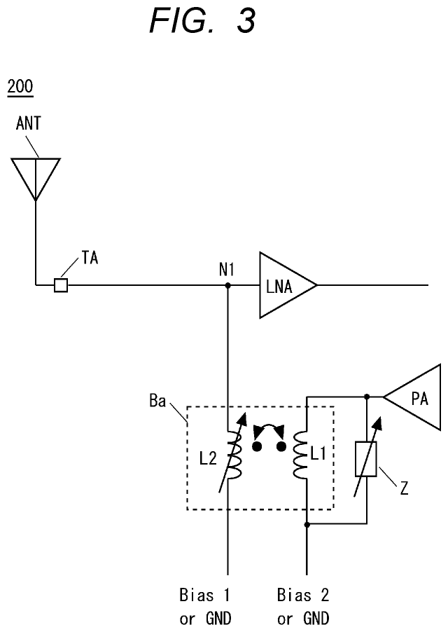

FIG. 3 is a diagram illustrating a configuration of a semiconductor device 200 according to the second embodiment. The second embodiment is an exemplary example of the first embodiment.

Comparing FIG. 1 and FIG. 3, a variable impedance Z is added. The variable impedance Z is coupled in parallel to the inductor L1.

The impedance of the variable impedance Z is configured to be variable. The impedance of the variable impedance Z is changed in accordance with a signal from a control circuit (not shown). The impedance of the variable impedance Z is controlled to be small during the reception operation and large during the transmission operation. Therefore, the impedance during the reception operation is smaller than the impedance during the transmission operation.

The variable impedance Z may be, for example, a variable capacitor. The capacitance value of the variable capacitor may be controlled to be large during the reception operation and small during the transmission operation. The variable impedance Z may be a switch. The switch may be controlled to an on state during the reception operation and to an off state during the transmission operation.

Since the impedance of the variable impedance Z is small during the reception operation, the inductance value of the secondary inductor is small. Since the impedance of the variable impedance is large during the transmission operation, the inductance value of the secondary inductor is large. Therefore, it is possible to prevent the reception performance from deteriorating due to mutual inductance. During the reception operation, the secondary inductor also serves as a path through which a direct current flows.

The second embodiment may vary the inductance of the secondary inductor.

### Modified Example

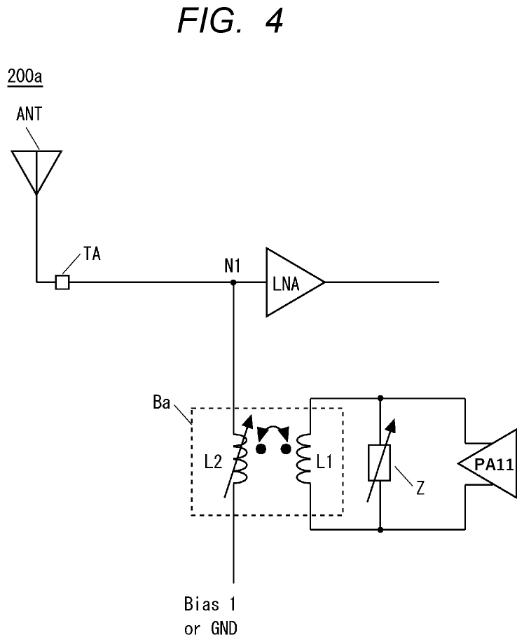

FIG. 4 is a diagram for explaining a configuration of a semiconductor device 200a according to a modified example of the second embodiment. Comparing FIG. 3 and FIG. 4, the power amplifier PA changes from a single-ended type to a differential type. A differential output terminal of the power amplifier PA11 is coupled to both ends of each of the inductor L1 and the variable impedance Z. The semiconductor device 200a in which the power amplifier PA11 is of a differential type has the same advantages as the semiconductor device 200.

### Third Embodiment

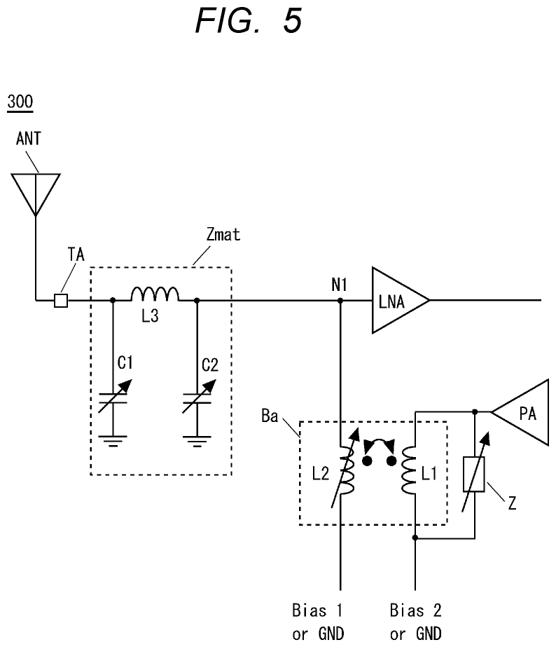

FIG. 5 is a diagram illustrating a configuration of a semiconductor device 300 according to the third embodiment. The third embodiment is an exemplary example of the second embodiment.

Comparing FIG. 3 and FIG. 5, an impedance matching Zmat is added to the path between the input node N1 and the antenna terminal TA of the low-noise amplifier LNA. The impedance matching circuit Zmat is a circuit in which an impedance matching circuit for reception and an impedance matching circuit for transmission are shared.

The impedance matching circuitry Zmat allows the semiconductor device 300 to efficiently transmit power to and from the antenna ANT. The impedance matching circuit Zmat may be mounted on a semiconductor-chip. As a result, the number of parts can be reduced, and the cost can be reduced.

The impedance matching circuitry Zmat may be, for example, a π-type LC filter. The impedance matching circuit Zmat comprises an inductor L3, a variable capacitor C1, and a variable capacitor C2. The inductor L3 is provided between the antenna terminal TA and the input node N1. The variable capacitor C1 is provided between one end of the inductor L3 and the ground. The variable capacitor C2 is provided between the other end of the inductor L3 and the ground.

Since the semiconductor device according to the third embodiment comprises the common impedance matching circuit Zmat, the area of the impedance matching circuit can be reduced and the cost can be reduced as compared with conventional technologies.

### Modified Example

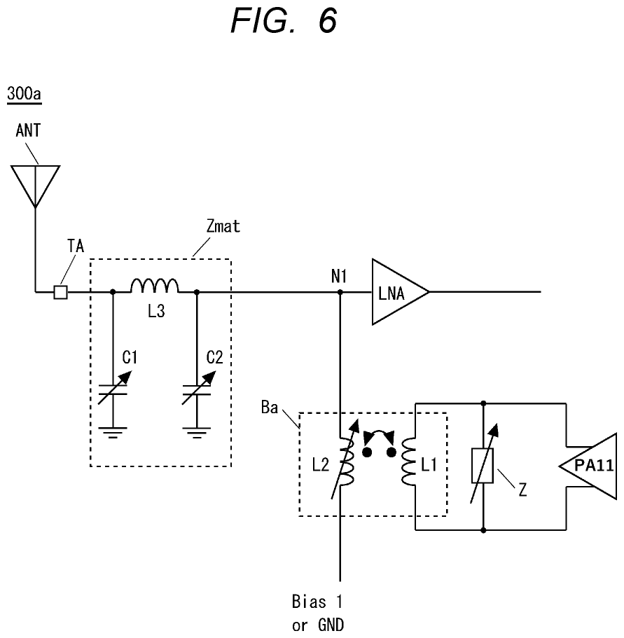

FIG. 6 is a diagram for explaining a configuration of a semiconductor device 300a according to a modified example of the third embodiment. Comparing FIG. 5 and FIG. 6, the power amplifier PA changes from a single-ended type to a differential type. A differential output terminal of the power amplifier PA11 is coupled to both ends of each of the inductor L1 and the variable impedance Z. In the semiconductor device 300a where the power amplifier PA11 is of a differential type, the same advantages as those of the semiconductor device 300 can be obtained.

### Fourth Embodiment

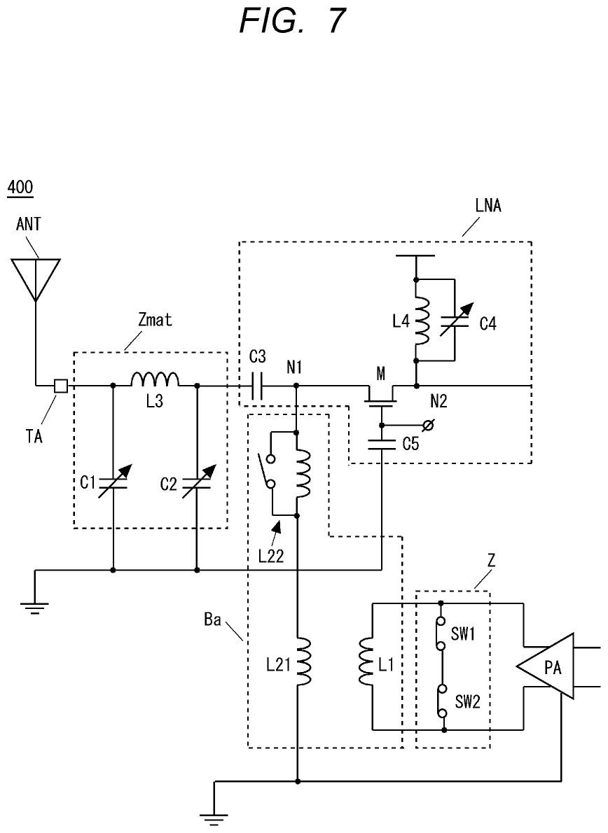

FIG. 7 is a diagram for explaining a configuration of the semiconductor device 400 according to the fourth embodiment. The fourth embodiment is an exemplary example of the third embodiment. The power amplifier PA may be of the single-ended type.

Comparing FIG. 6 to FIG. 7, an exemplary configuration of the low noise amplifier LNA is shown, an exemplary configuration of the variable impedance Z is shown, and an exemplary configuration of the balun circuit Ba is shown. The exemplary configuration of the impedance match circuit Zmat has been described above.

The low noise amplifier LNA is configured as a gate-grounded amplifier. The low noise amplifier LNA comprises a capacitor C3, nMOS transistor M, an inductor L4, a variable capacitor C4, and a capacitor C5.

A capacitor C3 is provided between the input node N1 of the amplifier circuit and the impedance matching circuit Zmat. Source and drain of the nMOS transistor M are provided between the input node N1 and an output node N2. The output node N2 is coupled to a power supply via the inductor L4 and the variable capacitor C4 which are coupled in parallel to each other. Gate of the nMOS transistor M is coupled to the voltage source, and is coupled to the ground via a capacitor C5.

The variable impedance Z comprises a switch SW1 and a switch SW2 coupled in series with each other. During the reception operation, each switch is controlled to be in an on state, and during the transmission operation, each switch is controlled to be in an off state.

The balun circuit Ba comprises the inductor L1, an inductor L21, and an inductor L22. The inductors L21 and L22 are coupled in series in this order between the input node N1 and the ground. That is, the inductor L2 described above comprises the inductor L21 and the inductor L22.

The inductor L21 has a mutual inductance with the inductor L1. The inductor L21 corresponds to the secondary inductor described above. The inductor L21 is a variable inductor. The inductance value (referred to as a first inductance value) of the inductor L21 varies depending on on/off of the switches SW1 and SW2. The first inductance value may be controlled to be small during the reception operation and large during the transmission operation. That is, in the reception operation, the inductance other than the inductor elements (e.g., choke coil) included in the inductor L22 is small.

The inductor L22 comprises a switch and an inductor element (e.g., choke coil) coupled in parallel to each other. The inductor L22 is a variable inductor. The switch is controlled to an off state during the reception operation and to an on state during the transmission operation. Therefore, the inductance value (referred to as a second inductance value) of the inductor L22 is controlled to be large in the reception operation and small in the transmission operation.

The inductor L22 may not have a mutual inductance with the inductor L1. Of course, the inductor L22 may also have a mutual inductance with the inductor L1.

The semiconductor device according to the fourth embodiment comprises a low noise amplifier of a gate-grounded type. Therefore, a wider bandwidth can be realized as compared with a conventional semiconductor device comprising a source-grounded low-noise amplifier.

### First Modified Example

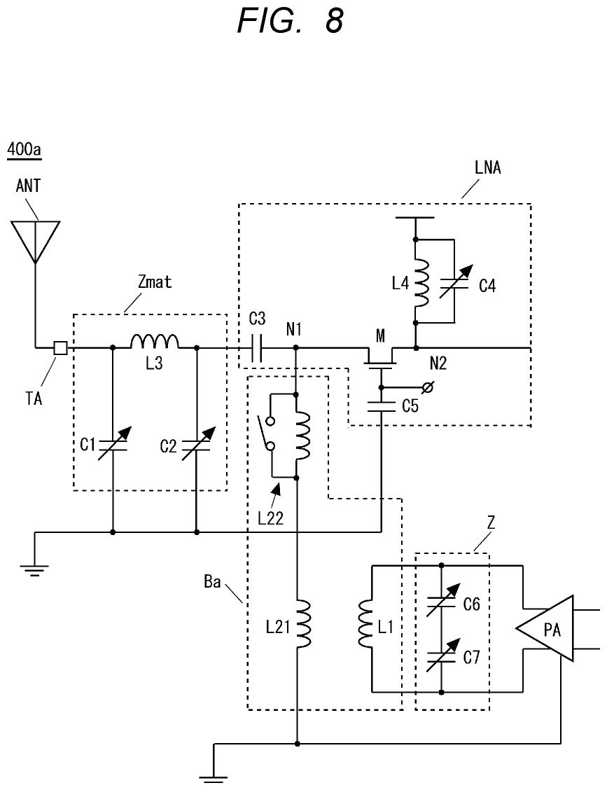

FIG. 8 is a diagram for explaining a configuration of a semiconductor device 400a according to a first modified example of the fourth embodiment. Comparing FIG. 7 and FIG. 8, a configuration of the variable impedance Z is different, and the switches SW1 and SW2 are replaced by variable capacitors C6 and C7, respectively. During the reception operation, the capacitance value of each variable capacitor increases, and during the transmission operation, the capacitance value of each variable capacitor is controlled to decrease. Accordingly, the impedance of the variable impedance Z is controlled to be small during the reception operation, and the impedance of the variable impedance Z is controlled to be large during the transmission operation. The semiconductor device 400a according to the first modified example of the fourth embodiment can also have the same advantages as those of the semiconductor device 400.

### Second Modified Example

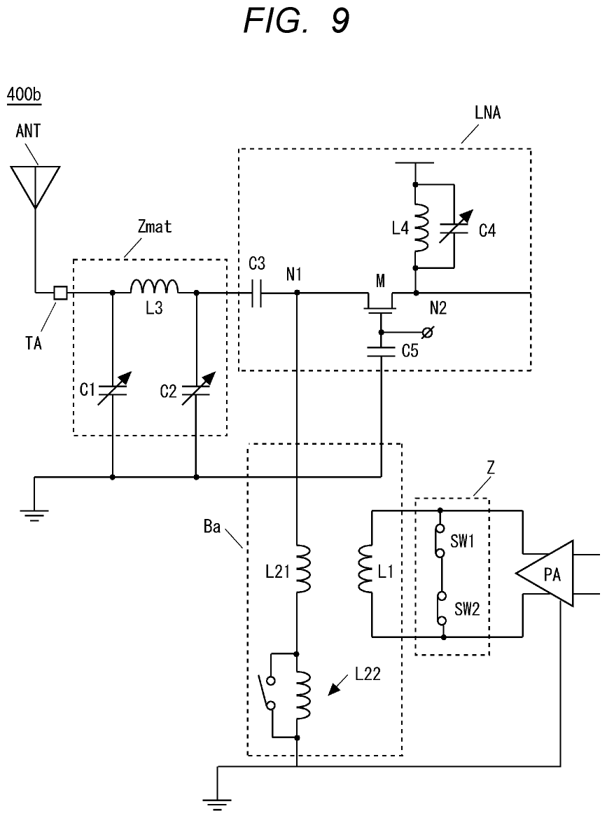

FIG. 9 is a diagram for explaining a configuration of a semiconductor device 400b according to a second modified example of the fourth embodiment. Comparing FIG. 7 and FIG. 9, the inductor L22 is provided closer to the ground than the inductor L21. The semiconductor device 400b according to the first modified example of the fourth embodiment can also have the same advantages as those of the semiconductor device 400.

### Third Modified Example

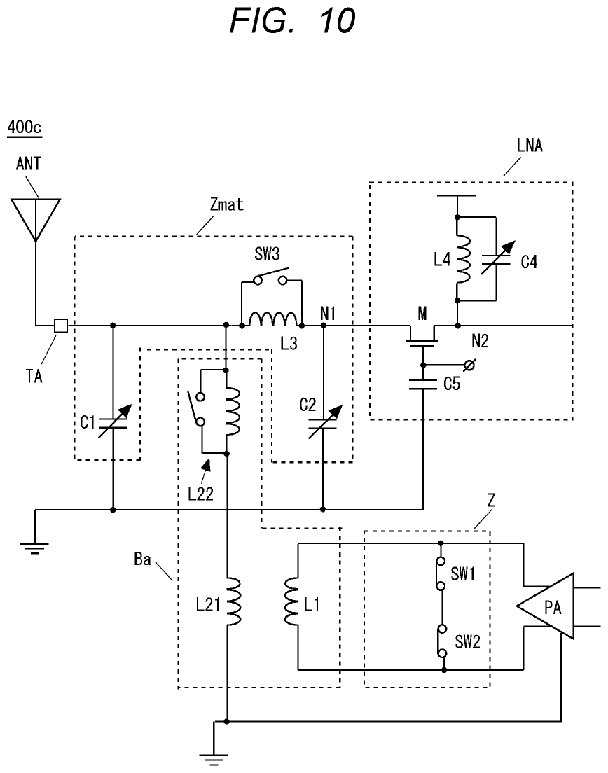

FIG. 10 is a diagram for explaining a configuration of a semiconductor device 400c according to a third modified example of the fourth embodiment. Comparing FIG. 7 and FIG. 10, the inductor L3 and the variable capacitor C2 included in the impedance matching circuit Zmat are different in position, and a switch SW3 coupled in parallel to the inductor L3 is added.

One end of the inductor L3 is coupled to the input node N1, and the other end of the inductor L3 is coupled to one end of the inductor L22. The capacitor C2 is provided between the input node N1 and the ground.

The switch SW3 is controlled to an off state during the reception operation and to an on state during the transmission operation. Accordingly, the high-frequency signal received by the antenna ANT can be efficiently absorbed, and the transmitted signal can be reduced.

The semiconductor device 400c according to the third modified example of the fourth embodiment can also have the same advantages as those of the semiconductor device 400.

Although the disclosure made by the present inventor has been specifically described based on the embodiment, the present disclosure is not limited to the embodiment described above, and it is needless to say that various modifications can be made without departing from the gist thereof.

What is claimed is:

1. A balun circuit provided between a transmitter and a common antenna terminal to which the transmitter and a receiver are coupled, the balun circuit comprising:
a first inductor coupled at one or both ends to the transmitter; and
a second inductor provided between an input node of the receiver, and ground or a first bias power supply,
wherein the second inductor comprises an inductor having a mutual inductance with the first inductor, and the second inductor is a variable inductor.

2. The balun circuit according to the claim 1, wherein the transmitter and the receiver operate exclusively from each other.

3. The balun circuit according to the claim 1, wherein the other end of the first inductor is coupled to the ground or a second bias power supply.

4. The balun circuit according to the claim 1, wherein an inductance value of the second inductor differs between a reception operation and a transmission operation.

5. The balun circuit according to the claim 4, wherein the inductance value of the second inductor during the reception operation is larger than the inductance value of the second inductor during the transmission operation.

6. The balun circuit according to the claim 1, wherein the second inductor comprises:
a secondary inductor having a mutual inductance with the first inductor; and
a choke coil coupled in series to the secondary inductor,
wherein a switch coupled in parallel to the choke coil is controlled to an off state during the reception operation and to an on state during the transmission operation.

7. The balun circuit according to the claim 6, wherein an inductance value of the secondary inductor during the reception operation is smaller than an inductance value of the secondary inductor during the transmission operation.

8. A semiconductor device comprising:
a transmitter;
a receiver; and
a balun circuit provided between the transmitter and a common antenna terminal to which the transmitter and the receiver are coupled,
wherein the balun circuit further comprises:
a first inductor coupled at one or both ends to the transmitter; and
a second inductor provided between an input node of the receiver, and ground or a first bias power supply,
wherein the second inductor comprises an inductor having a mutual inductance with the first inductor, and the second inductor is a variable inductor.

9. The semiconductor device according to the claim 8, further comprising:
a power amplifier provided in a last stage of the transmitter; and
a low noise amplifier provided at a first stage of the receiver,
wherein the common antenna terminal is provided between the power amplifier and the low noise amplifier, and the balun circuit is provided between the power amplifier and the common antenna terminal.

10. The semiconductor device according to the claim 9, wherein the low noise amplifier is a gate grounded amplifier circuit.

11. The semiconductor device according to the claim 8, wherein the transmitter and the receiver operate exclusively from each other.

12. The semiconductor device according to the claim 8, wherein the other end of the first inductor is coupled to the ground or a second bias power supply.

13. The semiconductor device according to the claim 8, wherein an inductance value of the second inductor differs between a reception operation and a transmission operation.

14. The semiconductor device according to the claim 8, wherein the inductance value of the second inductor during the reception operation is larger than the inductance value of the second inductor during the transmission operation.

15. The semiconductor device according to the claim 8, wherein the second inductor comprises:
a secondary inductor having a mutual inductance with the first inductor, and
a choke coil coupled in series to the secondary inductor,
wherein a switch coupled in parallel to the choke coil is controlled to an off state during the reception operation and to an on state during the transmission operation.

16. The semiconductor device according to the claim 15, wherein an inductance value of the secondary inductor during the reception operation is smaller than an inductance value of the secondary inductor during the transmission operation.

17. The semiconductor device according to the claim 16, further comprising:
a variable impedance coupled in parallel to the first inductor,
wherein the inductance value of the secondary inductor is changed by the variable impedance.

18. The semiconductor device according to the claim 8, further comprising:
an impedance matching circuit provided between the common antenna terminal and the input node.

19. The semiconductor device according to the claim 9, wherein the low noise amplifier, the power amplifier, and the balun circuit are formed on a single semiconductor chip.
